(19) United States
(12) Patent Application Publication
(10) Pub. No.: US 2026/0123350 A1
(43) Pub. Date: Apr. 30, 2026

(54) SEMICONDUCTOR MANUFACTURING EQUIPMENT

(71) Applicant: Kioxia Corporation, Tokyo (JP)

(72) Inventors: Toshiyuki SASAKI, Yokkaichi Mie (JP); Junichi HASHIMOTO, Yokkaichi Mie (JP)

(73) Assignee: Kioxia Corporation, Tokyo (JP)

(21) Appl. No.: 19/417,720

(22) Filed: Dec. 12, 2025

(30) Foreign Application Priority Data
Sep. 17, 2015 (JP) 2025-154564

(51) Int. Cl. H10P 72/76; H01J 37/32; H10P 50/00; H10P 50/24; H10P 58/00

(52) U.S. Cl. CPC H10P 72/7612; H01J 37/32642; H01J 37/32715; H10P 50/242; H10P 50/693; H10P 58/20

(57) ABSTRACT

According to an embodiment, semiconductor manufacturing equipment includes a processing chamber for processing a substrate on which a photoresist film is formed, a stage configured to support the substrate, an annular edge ring configured to enclose the substrate, an annular guard ring configured to cover a circumferential edge of the substrate from above, and a conveyor configured to convey at least the guard ring, in which the guard ring is configured to have an inner circumferential end located between an outer circumferential end of the substrate supported on the stage and an outer circumferential end of the photoresist film.

### CROSS-REFERENCE TO RELATED APPLICATION

This application is based upon and claims the benefit of priority from Japanese Patent Application No. 2025-154564, filed on Sep. 17, 2025, the entire contents of which are incorporated herein by reference.

### BACKGROUND OF THE INVENTION

### Field of the Invention

Embodiments relate to semiconductor manufacturing equipment.

### Description of the Related Art

As semiconductor manufacturing equipment, dry etching equipment has been known that includes a chuck mechanism housed in a vacuum container and intended for fixing a wafer and a cover ring that covers, or is located above, an upper surface of a peripheral part of the wafer.

### BRIEF DESCRIPTION OF THE DRAWINGS

FIG. 1 shows an overall configuration of semiconductor manufacturing equipment according to a first embodiment;

FIG. 2 shows a top view and a side view of an edge ring and a substrate placed on a stage;

FIG. 3 is a bottom view of a guard ring according to the first embodiment;

FIG. 4 is a top view of lift pins according to the first embodiment;

FIG. 5 is a bottom view of a conveyor according to the first embodiment;

FIG. 6 is a flowchart showing steps of a method for manufacturing semiconductor devices according to the embodiment;

FIG. 7A is an explanatory diagram of the method for manufacturing semiconductor devices according to the embodiment;

FIG. 7B is an explanatory diagram of the method for manufacturing semiconductor devices according to the embodiment;

FIG. 7C is an explanatory diagram of the method for manufacturing semiconductor devices according to the embodiment;

FIG. 7D is an explanatory diagram of the method for manufacturing semiconductor devices according to the embodiment;

FIG. 7E is an explanatory diagram of the method for manufacturing semiconductor devices according to the embodiment;

FIG. 7F is an explanatory diagram of the method for manufacturing semiconductor devices according to the embodiment;

FIG. 7G is an explanatory diagram of the method for manufacturing semiconductor devices according to the embodiment;

FIG. 7H is an explanatory diagram of the method for manufacturing semiconductor devices according to the embodiment;

FIG. 7I is an explanatory diagram of the method for manufacturing semiconductor devices according to the embodiment;

FIG. 7J is an explanatory diagram of the method for manufacturing semiconductor devices according to the embodiment;

FIG. 7K is an explanatory diagram of the method for manufacturing semiconductor devices according to the embodiment;

FIG. 8 is an explanatory diagram of a conventional method for manufacturing semiconductor devices;

FIG. 9 shows an overall configuration of semiconductor manufacturing equipment according to a second embodiment;

FIG. 10 is a cross-sectional view showing a configuration of and around the edge ring of FIG. 9;

FIG. 11 is a cross-sectional view showing a configuration of semiconductor manufacturing equipment according to a third embodiment; and

FIG. 12 shows an application example of semiconductor devices according to some embodiments.

### DETAILED DESCRIPTION OF THE INVENTION

Hereinafter, some embodiments will be described with reference to the accompanied drawings. For easy understanding of the description, the same components in the respective drawings have the same reference characters allotted wherever possible, and repeated description thereof will be omitted.

### 1. First Embodiment

### [Basic Configuration]

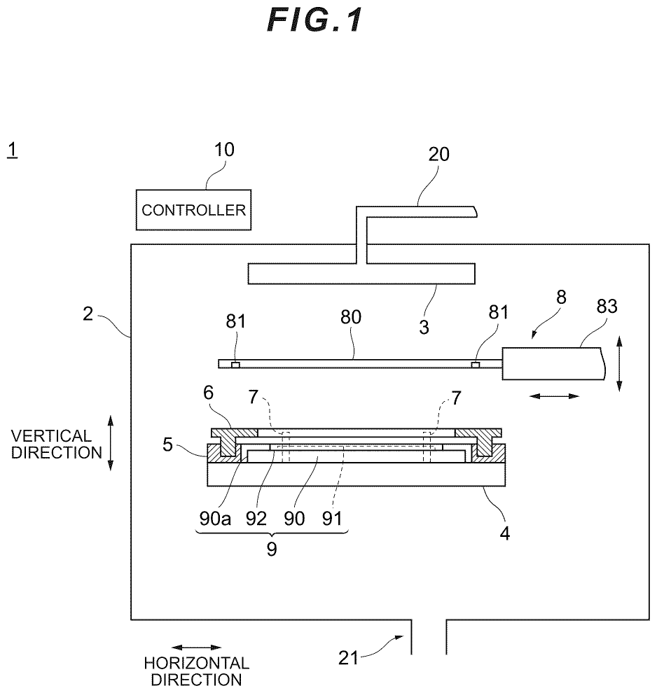

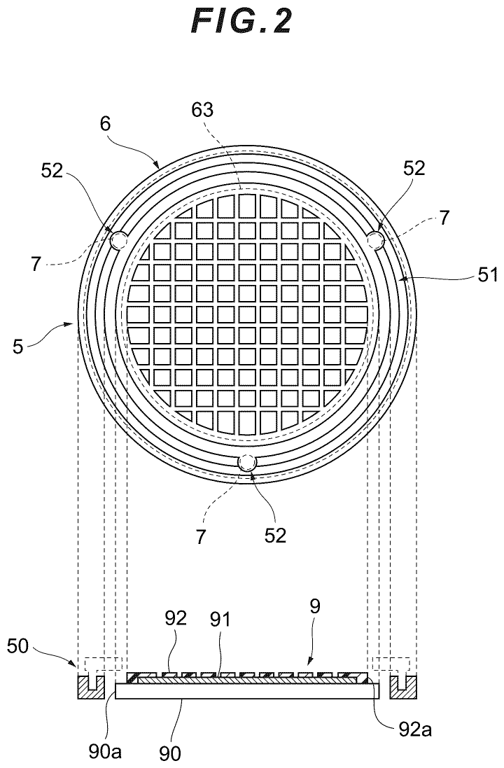

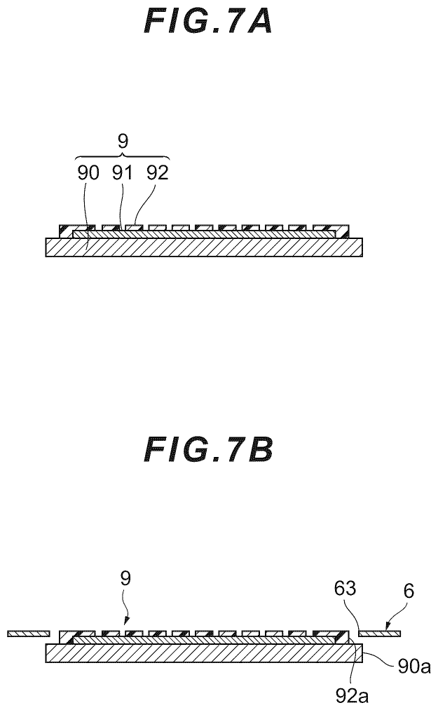

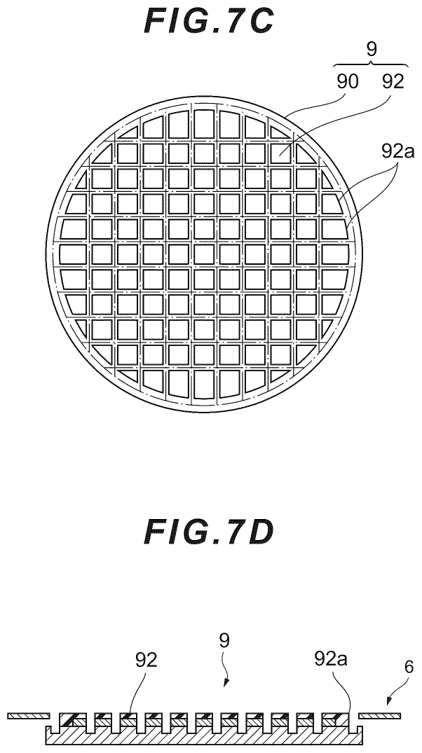

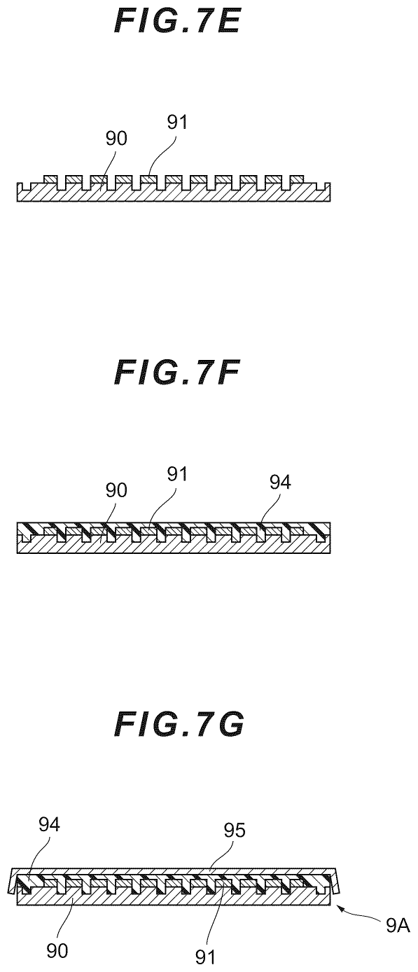

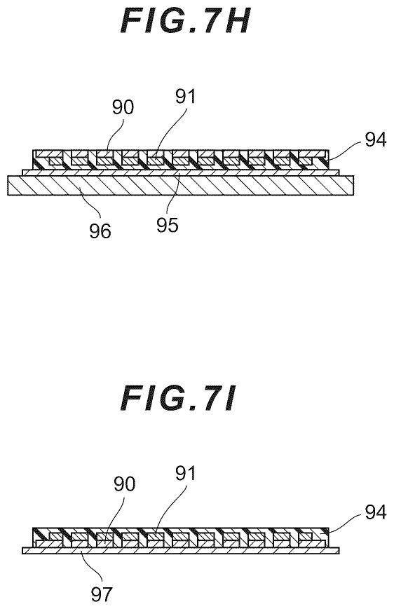

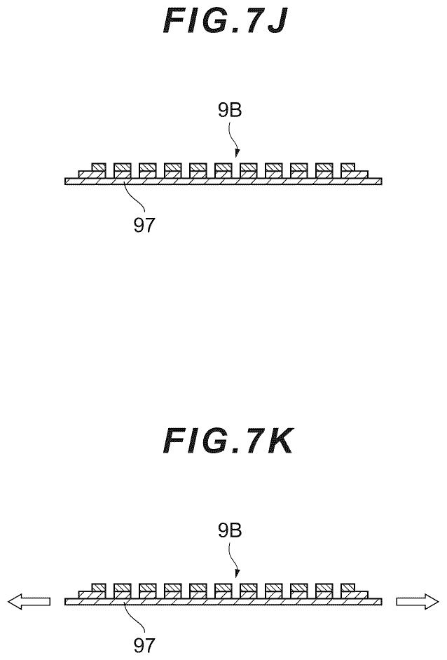

FIG. 1 shows an overall configuration of semiconductor manufacturing equipment 1 (hereinafter also referred to simply as the “equipment 1”) according to a first embodiment. The following description will be given using directions shown in FIG. 1 as bases. The equipment 1 is configured as dry etching equipment, for example, and dices a substrate 9 through dry etching such as reactive ion etching (RIE) to manufacture semiconductor devices as chips 9B (see FIG. 7J). The substrate 9 has a silicon wafer 90, a device film 91, and a photoresist film 92 (hereinafter also referred to simply as the “resist film 92”). The device film 91 is a thin film stacked on a surface of the silicon wafer 90 to form a cell array and the like, and includes an oxide film, a metal film, and the like. The resist film 92 is a thin film formed of a mixture of resin, a photosensitizing agent, and the like, and is stacked mainly on a surface of the device film 91 to form any mask pattern. The resist film 92 according to the present embodiment forms a grid-like mask pattern (see FIG. 2), and dry etching is performed in accordance with this mask pattern as will be described later.

The equipment 1 includes a processing chamber 2 as well as an electrode 3 and a stage 4 each provided in the processing chamber 2. The processing chamber 2 is a chamber for processing the substrate 9 in a vacuum environment, and has an introducing part 20 for introducing corrosive gas into the processing chamber 2 and a depressurization mechanism 21 for depressurizing the interior of the processing chamber 2. The depressurization mechanism 21 has, for example, an exhaust pipe conduit connected to an inner space of the processing chamber 2 and a vacuum pump not shown. The electrode 3 is connected to a high-frequency power supply not shown and applies high-frequency power to corrosive gas introduced through the introducing part 20, thereby producing plasma for performing reactive ion etching in the processing chamber 2. The stage 4 is arranged to be opposite to the electrode 3, and is configured to support the substrate 9 and is also configured as an electrode to be paired with the electrode 3. When dry etching is performed, the substrate 9 is supported by the stage 4 from below such that the resist film 92 faces upward. The stage 4 may be movable at least in one of the vertical direction and the horizontal direction. The stage 4 may also be configured to function as a chuck table for fixing the substrate 9 placed on its upper surface.

The equipment 1 further includes an annular edge ring 5, an annular guard ring 6, lift pins 7 provided for the stage 4, a conveyor 8, and a controller (an electric controller) 10.

### [Edge Ring]

The edge ring 5 is also referred to as a focus ring and is composed of an insulator such as silicon or silicon carbide (SiC) or ceramic, for example. FIG. 2 shows a top view and a side view of the edge ring 5 and the substrate 9 placed on the stage 4. The edge ring 5 is configured to be placed on the stage 4 such that an upper surface portion 50 faces upward and to enclose the substrate 9 in a state supported on the stage 4 along the whole circumference from the radially outer side. The edge ring 5 is comparable in thickness to the substrate 9. The edge ring 5 thereby prevents etching properties from becoming non-uniform at an outer circumferential end 90a of the substrate 9 and in its vicinity when dry etching is performed. The edge ring 5 has a width smaller by approximately 1 mm than a conventional width (for example, 50 mm) as compared with a conventional edge ring having the same outer diameter, in order to be aligned with the guard ring 6 which will be described later. Note that the edge ring 5 has an inner diameter larger than the diameter of the substrate 9, and when the substrate 9 is arranged on the inner side of the edge ring 5, a clearance is produced between an inner circumferential end of the edge ring 5 and the outer circumferential end 90a. A groove-like recess 51 extending in the circumferential direction is formed in the upper surface portion 50 of the edge ring 5 according to the present embodiment. The recess 51 is engageable with a projection 61 of the guard ring 6 which will be described later by receiving the projection 61.

Furthermore, the edge ring 5 according to the present embodiment has three notches 52 formed to be recessed in an arc shape when viewed from above from its inner circumferential end toward the radially outer side. The lift pins 7 which will be described later are insertable through the notches 52, respectively. In other words, the edge ring 5 according to the present embodiment is positioned on the stage 4 by the notches 52 and the lift pins 7.

### [Guard Ring]

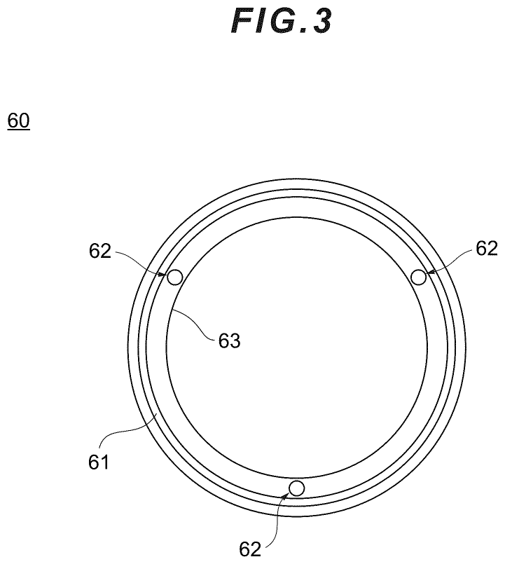

The guard ring 6 is also referred to as a cover ring and is composed of alumina, quartz, silicon carbide (SiC), or the like, for example. The guard ring 6 is configured to cover from above a circumferential edge of the substrate 9 in the state supported on the stage 4. The guard ring 6 thereby protects the substrate 9 such that the outer circumferential end 90a and the silicon wafer 90 in its vicinity are not scraped when dry etching is performed. FIG. 3 is a bottom view of the guard ring 6. As shown in FIG. 3, the guard ring 6 according to the present embodiment has a lower surface portion 60 opposed to the upper surface portion 50 of the edge ring 5 when arranged on the stage 4. The projection 61 extending in the circumferential direction and projecting downward is formed on the lower surface portion 60. The projection 61 is engageable with the recess 51 by being fitted into the recess 51. When the recess 51 and the projection 61 are engaged, the guard ring 6 is aligned to be substantially concentric with the edge ring 5. Furthermore, three circular hollows 62 that are open at the lower surface and are hollowed upward are formed in the lower surface portion 60 of the guard ring 6 according to the present embodiment. Leading ends of the lift pins 7 which will be described later are engageable with the hollows 62, respectively.

### [Lift Pin]

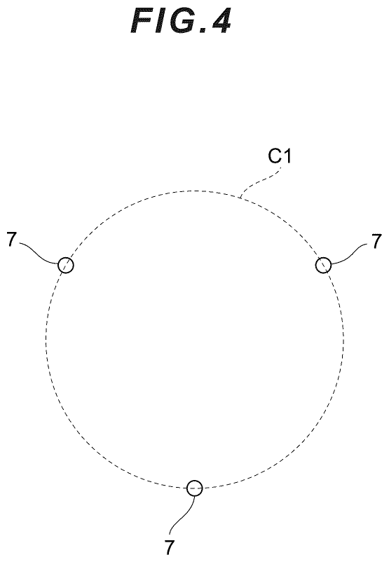

The lift pins 7 are configured to project upward from the stage 4 and support the guard ring 6. As shown in FIG. 4, the three lift pins 7 according to the present embodiment are arranged at intervals on the circumference of a virtual circle C1 when viewed from above. The virtual circle C1 has a diameter larger than the inner diameter of the edge ring 5 and smaller than the outer diameter of the edge ring 5. When the edge ring 5 is arranged to be concentric with the virtual circle C1, the lift pins 7 are aligned with the notches 52, respectively. When the guard ring 6 is arranged to be concentric with the virtual circle C1, the leading ends of the lift pins 7 are fitted into the hollows 62, respectively, so that the lift pins 7 and the hollows 62 are engaged. In other words, in a state in which the recess 51 and the projection 61 are engaged, in which the lift pins 7 are inserted through the notches 52, respectively, and furthermore, in which the leading ends of the lift pins 7 are engaged with the hollows 62, respectively, the virtual circle C1, the edge ring 5, and the guard ring 6 are concentric or substantially concentric. At this time, the guard ring 6 is aligned such that its inner circumferential end 63 is located between the outer circumferential end 90a of the substrate 9 supported on the stage 4 and an outer circumferential end 92a (see FIG. 2) of the resist film 92. Herein, the outer circumferential end 92a of the resist film 92 is a generic term of edges located on the radially outermost side in the substrate 9 among edges that the respective resist films 92 have.

Hereinafter, such a position of the guard ring 6 in the horizontal direction that the inner circumferential end 63 is located between the outer circumferential end 90a and the outer circumferential end 92a will also be referred to as a “prescribed position”. The distance in the horizontal direction between the inner circumferential end 63 at the prescribed position and the outer circumferential end 92a preferably exceeds 0 μm and is less than 200 μm. A reason why the guard ring 6 is aligned at the prescribed position will be described later.

Each of the lift pins 7 may be immovable relative to the stage 4 or may be movable upward/downward relative to the stage 4. For example, the lift pins 7 may be configured to transition between the state projecting from the stage 4 and a state hidden in the stage 4 according to necessity. The stage 4 may be further provided with a plurality of lift pins configured to be movable upward/downward relative to the stage 4 in a region on the inner side of the virtual circle C1, separately from the lift pins 7. These lift pins project upward from the stage 4 and are hidden in the stage 4 to assist an operation of a publicly-known wafer conveyance robot or the like placing the substrate 9 on the stage 4.

### [Conveyor]

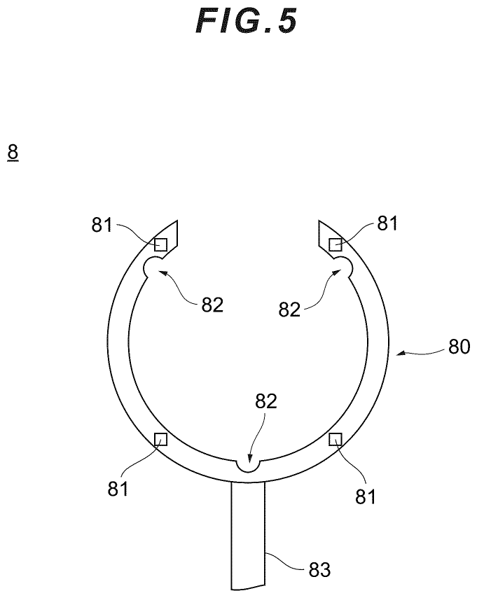

FIG. 5 is a bottom view of the conveyor 8. The conveyor 8 is movable at least in the vertical direction and the horizontal direction and is configured to convey at least the guard ring 6 in the processing chamber 2. The conveyor 8 has an arm portion 80 having a generally arc shape when viewed from above and a shaft portion 83 connected to the arm portion 80 and serving as a base end of the arm portion 80. The arm portion 80 is configured to support the guard ring 6 from below while being in contact with the circumferential edge of the lower surface portion 60 of the guard ring 6. The shaft portion 83 moves the arm portion 80 and the guard ring 6 supported by the arm portion 80, by means of a moving mechanism not shown such as an actuator.

Optical sensors 81 are provided on the lower surface side of the arm portion 80. The optical sensor 81 can be, but is not particularly limited to, a sensor having a light emitting element such as a light emitting diode and a light receiving element such as a phototransistor or photodiode, for example, and capable of detecting an object present at a certain distance from the sensor itself. The optical sensor 81 detects the recess 51 when the arm portion 80 approaches the edge ring 5 on the stage 4. The optical sensor 81 is configured to output a detection signal to the controller 10 which will be described later, and the controller 10 controls the position of the shaft portion 83 based on an output of the optical sensor 81. When conveying the guard ring 6, the conveyor 8 thus conveys the guard ring 6 onto the edge ring 5 such that the projection 61 and the recess 51 are engaged. The arm portion 80 has three notches 82 formed to be hollowed in an arc shape when viewed from above from its inner circumferential end toward the radially outer side. When the conveyor 8 conveys the guard ring 6 to the prescribed position and subsequently moves down so as to place the guard ring 6 on the edge ring 5 and the lift pins 7, the lift pins 7 are inserted through the notches 82, respectively. In other words, the arm portion 80 is configured to avoid interference with the lift pins 7. Note that when the guard ring 6 is placed on the arm portion 80, the hollows 62 of the guard ring 6 are aligned to the notches 82, respectively, to further facilitate conveyance of the guard ring 6 to the prescribed position.

### [Controller]

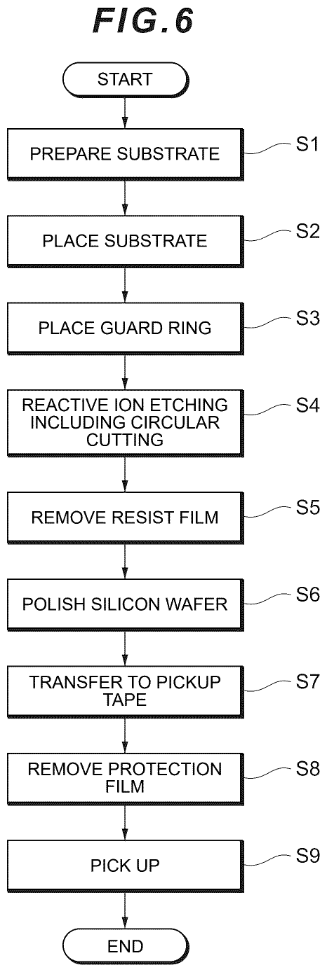

The controller 10 controls operations of the equipment 1. The controller 10 can be configured by a general-purpose computer as hardware, and includes a processor such as a CPU (central processing unit) or a GPU (graphics processing unit), a volatile memory such as a RAM (random access memory), a non-volatile memory such as a flash memory, and the like. The non-volatile memory stores a program for controlling operations of the equipment 1. For performing common dry etching, the controller 10 is configured to control operations of the introducing part 20, the depressurization mechanism 21, the stage 4, and the conveyor 8. In addition, the controller 10 is configured to perform finer position adjustment of the conveyor 8 based on output signals from the optical sensors 81 when the guard ring 6 is conveyed.

[Alignment Mechanism] As described above, the recess 51 of the edge ring 5, the projection 61 of the guard ring 6, the hollows 62, the lift pins 7, the optical sensors 81 of the conveyor 8, and the controller 10 constitute an alignment mechanism for aligning the guard ring 6 to the prescribed position. This alignment mechanism simplifies a step of manufacturing diced semiconductor devices from the substrate 9 in the method for manufacturing semiconductor devices using the equipment 1.
[Method For Manufacturing Semiconductor Devices] FIG. 6 is a flowchart showing steps of the method for manufacturing semiconductor devices using the equipment 1, and FIGS. 7A to 7K are explanatory diagrams of the method for manufacturing semiconductor devices. Hereinafter, the method for manufacturing semiconductor devices using the equipment 1 will be described with reference to these drawings.

First, the substrate 9 as shown in FIG. 7A is prepared (step S1). As described above, the substrate 9 has the silicon wafer 90, the device film 91, and the resist film 92, and at the time point of step S1, is in a state in which the cell array and the like have already been formed by the device film 91 and in which a dicing pattern has been formed by the resist film 92.

Subsequently, the substrate 9 is placed on the inner side of the edge ring 5 on the stage 4 such that the resist film 92 faces upward (step S2). The method for placing the substrate 9 can be, but is not particularly limited to, conveying the substrate 9 from the outside of the processing chamber 2 into the interior of the processing chamber 2 using a publicly-known wafer conveyance robot, for example, and subsequently placing the substrate 9 on the inner side of the edge ring 5. Note that as described above, the edge ring 5 is positioned in advance on the stage 4 to be concentric with the virtual circle C1 and such that the lift pins 7 are inserted through the notches 52, respectively.

Subsequently, the guard ring 6 is aligned to the prescribed position by the conveyor 8 and furthermore is placed on the edge ring 5 and the lift pins 7 (step S3). At this time, as described above, it is preferable that the hollows 62 of the guard ring 6 should be aligned in advance to the notches 82, respectively. When step S3 is completed, the inner circumferential end 63 of the guard ring 6 is located between the outer circumferential end 90a of the substrate 9 and the outer circumferential end 92a of the resist film 92 as shown in FIG. 7B. The conveyor 8 retracts to the outside of the processing chamber 2 after placing the guard ring 6 on the edge ring 5 and the lift pins 7.

Subsequently, plasma is produced in the processing chamber 2, and the device film 91 and the silicon wafer 90 are cut to a predetermined depth along the dicing pattern through reactive ion etching (step S4). Such a step is commonly referred to also as “plasma dicing”. In step S4, the silicon wafer 90 between the inner circumferential end 63 of the guard ring 6 and the outer circumferential end 92a of the resist film 92 is also cut circularly to the predetermined depth through dry etching using the same plasma in parallel to this plasma dicing. In other words, in step S4, a location indicated by a dash-dotted line in FIG. 7C is subjected to dry etching not only to segment the device film 91 in accordance with the mask pattern of the resist film 92 but also to simultaneously perform preprocessing for cutting out a region of the circumferential edge at which the device film 91 is not formed from the substrate 9. Hereinafter, such circular cutting for preprocessing will also be referred to as “circular cutting”. When step S4 is completed, the silicon wafer 90 is in a half-cut state at clearances between the resist films 92 and at the outer side of the outer circumferential end 92a as shown in FIG. 7D. As will be described later, steps after step S4 are simplified by performing circular cutting.

Subsequently, the resist films 92 are removed (step S5). The method for removing the resist films 92 can include, but is not particularly limited to, methods such as, for example, introducing appropriate gas into the processing chamber 2 to perform plasma ashing and exposing the substrate 9 taken out from the processing chamber 2 to an appropriate photoresist stripping solution to dissolve the resist films 92. These methods may be used in combination. When step S5 is completed, a substrate from which the resist films 92 have been removed is obtained as shown in FIG. 7E.

Subsequently, the silicon wafer 90 is polished (step S6). Prior to polishing, it is preferable to first stack a protection film 94 on the silicon wafer 90 and the device film 91 for protecting them as shown in FIG. 7F and subsequently to affix a protection tape 95 to the protection film 94 from above as shown in FIG. 7G. The protection film 94 is intended to prevent the device film 91 from coming into direct contact with the protection tape 95 and can be formed as appropriate by applying an alkaline material, for example. A substrate 9A obtained as shown in FIG. 7G is arranged on an electrostatic chuck table 96 in such a posture that the device film 91 faces downward, for example. Then, the surface of the silicon wafer 90 facing upward is polished to a cut mark formed in step S4. When step S6 is completed, the silicon wafer 90 and the device film 91 as stacked are separated into pieces in the state held by the protection tape 95 as shown in FIG. 7H.

Subsequently, the silicon wafer 90 and the device film 91 in the state held by the protection tape 95 are transferred to a pickup tape 97 (step S7). Step S7 can be performed by, for example, affixing the pickup tape 97 to a surface of the silicon wafer 90 opposite to the surface on which the device film 91 is stacked and thereafter stripping the protection tape 95. When step S7 is completed, the pieces of the silicon wafer 90 and the device film 91 in the state protected by the protection film 94 are obtained in the state held by the pickup tape 97 as shown in FIG. 7I.

Subsequently, the protection film 94 is removed from the pieces of the silicon wafer 90 and the device film 91 in the state protected by the pickup tape 97 (step S8). Removal of the protection film 94 can be performed by a publicly-known method such as dissolving the protection film 94 by a predetermined solvent. When step S8 is completed, the plurality of chips 9B in which the silicon wafer 90 and the device film 91 are stacked are obtained in the state held by the pickup tape 97 as shown in FIG. 7J.

Subsequently, the diced or separated chips 9B are picked up from the pickup tape 97 (step S9). The chips 9B can be picked up in a state in which the pickup tape 97 is expanded by a device such as a publicly-known expander, for example, to widen (expand) the intervals among the chips 9B as shown in FIG. 7K.

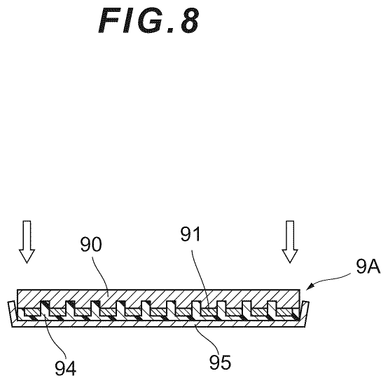

Diced semiconductor devices are manufactured through steps S1 to S9 above. A conventional semiconductor device is configured such that the inner circumferential end of the guard ring is located on the radially inner side relative to the outer circumferential end 92a of the resist film 92. Thus, a conventional method for manufacturing semiconductor devices fails to execute circular cutting described above in the step of performing plasma dicing. However, if left as it is, portions which should originally be the chips 9B might not be cut out from the circumferential edge of the silicon wafer 90 and might not be picked up as the chips 9B. Therefore, as shown in FIG. 8, a step of forming the protection film 94 and circularly cutting the silicon wafer 90 of the substrate 9A in the state held by the protection tape 95 from the surface opposite to the device film 91 (at a position indicated by arrows) has been performed in some cases. In other words, the conventional manufacturing method requires the step of circularly cutting the silicon wafer 90 to the predetermined depth to be performed at timing after plasma dicing and before polishing of the silicon wafer 90, in order to pick up all the chips 9B. In this respect, the equipment 1 described above allows a clearance necessary for circular cutting to be ensured between the inner circumferential end 63 of the guard ring 6 and the outer circumferential end 92a of the resist film 92 because of the alignment mechanism. Since the guard ring 6 also functions as a mask for circular cutting (through dry etching), the substrate 9 can be subjected to circular cutting at a more accurate position because of accurate alignment of the guard ring 6 to the edge ring 5. This enables the method for manufacturing semiconductor devices using the equipment 1 to include circular cutting in the step of plasma dicing, which can omit the step shown in FIG. 8 to simplify the steps until the chips 9B are manufactured. The foregoing is the reason why the guard ring 6 is aligned to the prescribed position.

In the equipment 1, the lift pins 7, the notches 52, and the hollows 62 may be omitted as appropriate. In other words, the alignment mechanism may be composed of the recess 51 of the edge ring 5, the projection 61 of the guard ring 6, the optical sensors 81 of the conveyor 8, and the controller 10.

### 2. Second Embodiment

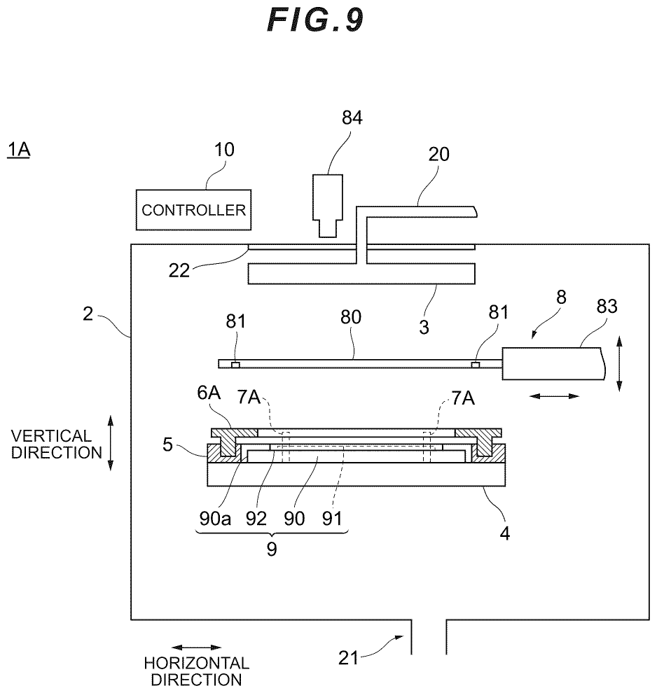

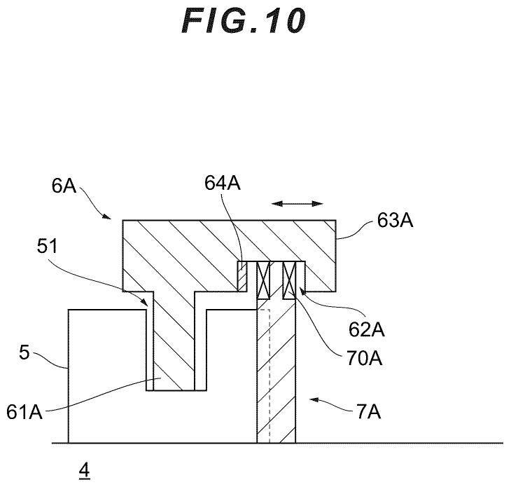

Next, semiconductor manufacturing equipment 1A (hereinafter also referred to simply as the “equipment 1A”) according to a second embodiment will be described with reference to FIGS. 9 to 10. In the following description, the same components as those of the equipment 1 have similar reference characters allotted, and description thereof will be omitted.

FIG. 9 shows an overall configuration of the equipment 1A. As shown in FIG. 9, the equipment 1A includes another sensor 84 in addition to the optical sensors 81. The sensor 84 is not particularly limited as long as it can detect the outer circumferential end 92a of the resist film 92 in a non-contact manner, and can be configured by spectral interference film thickness measuring equipment, for example. Spectral interference film thickness measuring equipment including a camera (for example, a hyperspectral camera) that images the substrate 9 on the stage 4 is preferable in terms of the measuring speed. A place at which the sensor 84 is provided is not particularly limited as long as the outer circumferential end 92a can be detected, and can be a position at which, for example, the substrate 9 on the stage 4 can be imaged by the above-described camera from the outside of the processing chamber 2 through a transmission window 22 provided for the processing chamber 2. The sensor 84 measures a film thickness at each point on the substrate 9 and outputs a detection signal to the controller 10. The controller 10 specifies the position of the outer circumferential end 92a on the stage 4 based on this detection signal.

FIG. 10 is a cross-sectional view showing configurations of the edge ring 5, a guard ring 6A, and a lift pin 7A in the equipment 1A. The equipment 1A is the same as the equipment 1 in terms of the configuration of the edge ring 5 but is different from the equipment 1 in terms of the configurations of the guard ring 6A and the lift pin 7A. More specifically, a projection 61A that is engageable with the recess 51 of the edge ring 5 and a hollow 62A that is engageable with a leading end of the lift pin 7A are formed on and in a lower surface portion of the guard ring 6A. A magnetic body 64A is provided in a region located on the radially outer side on an inner wall of the hollow 62A. The projection 61A has the same configuration as that of the projection 61.

Electromagnets 70A are provided at the leading end of the lift pin 7A. The electromagnets 70A are connected to a current source not shown, and an amount of current to be supplied from the current source to the electromagnets 70A is controlled by the controller 10 based on the detection signal output from the sensor 84. The controller 10 controls the amount of current to be supplied to each of the electromagnets 70A and adjusts a magnetic force of each of the electromagnets 70A to finely adjust the position of an inner circumferential end 63A of the guard ring 6A. In other words, the equipment 1A finely adjusts the position in the horizontal direction of the guard ring 6A in a state in which the recess 51 and the projection 61A are engaged with each other and in which the hollow 62A and the lift pin 7A are engaged with each other.

As described above, in the equipment 1A, the recess 51 of the edge ring 5, the projection 61A of the guard ring 6A, the hollow 62A, the magnetic body 64A, the electromagnets 70A of the lift pin 7A, the optical sensors 81, the sensor 84, and the controller 10 constitute the alignment mechanism.

### 3. Third Embodiment

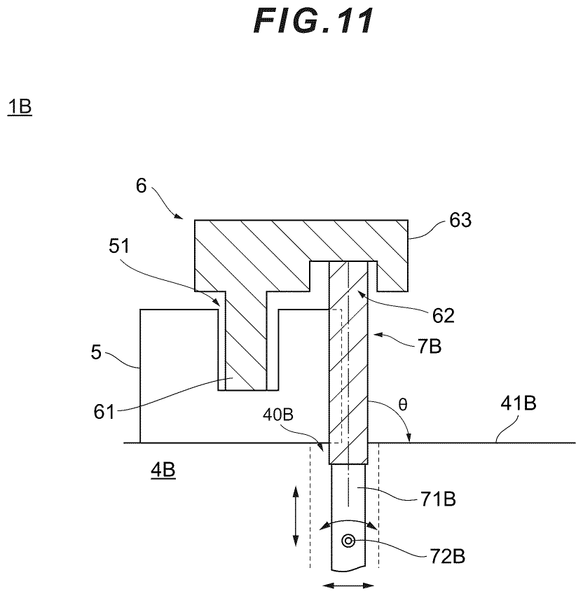

Next, semiconductor manufacturing equipment 1B (hereinafter also referred to simply as the “equipment 1B”) according to a third embodiment will be described with reference to FIG. 11. In the following description, the same components as those of the equipment 1 and the equipment 1A have similar reference characters allotted, and description thereof will be omitted.

The equipment 1B includes the edge ring 5 and the guard ring 6 similar to those of the equipment 1. The equipment 1B also includes the sensor 84 similar to that of the equipment 1A. However, as shown in FIG. 11, the equipment 1B is different from the equipment 1 and the equipment 1A in terms of configurations of a stage 4B and lift pins 7B. An opening 40B in which a base end portion 71B of the lift pin 7B is to be buried is formed in the stage 4B. The base end portion 71B is connected to at least one of a turning shaft 72B and a moving mechanism not shown and, in the opening 40B, can rotate around the turning shaft 72B or move in the horizontal direction. Accordingly, the lift pin 7B is configured to be changeable in at least one of a position in an in-plane direction parallel to an upper surface 41B of the stage 4B and an inclination angle θ relative to the upper surface 41B. In addition, the lift pin 7B may be configured to be changeable in position in the vertical direction. The controller 10 controls at least one of the position in the in-plane direction of each of the lift pins 7B and the inclination angle θ based on the detection signal output from the sensor 84. Accordingly, at least one of the position in the horizontal direction of the guard ring 6 and an inclination relative to the horizontal plane is finely adjusted in the state in which the recess 51 and the projection 61 are engaged with each other and in which the hollow 62 and the lift pin 7B are engaged with each other.

As described above, in the equipment 1B, the recess 51 of the edge ring 5, the projection 61 of the guard ring 6, the hollow 62, the lift pin 7B, the optical sensors 81, the sensor 84, and the controller 10 constitute the alignment mechanism.

### 4. Further Embodiments

The present disclosure is not limited to the above-described embodiments. For example, further embodiments as will be described below are conceivable. The following embodiments can be combined as appropriate.

The configurations of the processing chamber 2, the electrode 3, the stage 4, and the conveyor 8 can be changed as appropriate. For example, the arm portion 80 of the conveyor 8 may be changed in shape as appropriate, and the notches 82 may be omitted. For example, the conveyor 8 may be configured to be capable of conveying and placing the substrate 9 (at a predetermined position) by an approach such as increasing the area of the upper surface of the arm portion 80. In this case, the conveyor 8 and the controller 10 may be configured to place the substrate 9 while aligning the substrate 9 to a predetermined position on the inner side of the edge ring 5 using the optical sensor 81. The guard ring 6 can thereby be aligned to a prescribed position with higher accuracy. The shaft portion 83 may be configured to be rotatable around a shaft and incline the arm portion 80 relative to the horizontal direction. The optical sensor 81 is not particularly limited as long as it is capable of detecting target irregularities, and may be changed to a sensor such as a laser sensor or an ultrasonic sensor, for example. Furthermore, the sensor 84 for detecting the outer circumferential end 92a may be provided for the conveyor 8, for example.

A mechanism for engaging the edge ring 5 and the guard ring 6/6A is not limited to the engagement mechanism of the above-described embodiments. For example, the edge ring 5 may have a projection on the upper surface portion, and the guard ring 6/6A may have, in the lower surface portion, a recess to be engaged with the projection. The edge ring 5 and the guard ring 6/6A may each have both a projection and a recess such that the projection of the edge ring 5 is engaged with the recess of the guard ring 6/6A and such that the recess of the edge ring 5 is engaged with the projection of the guard ring 6/6A. Furthermore, the projection or recess of the edge ring 5 and the guard ring 6/6A may not be formed along the whole circumference.

The notches 52 of the edge ring 5 may be changed to through-holes through which the lift pins 7 are insertable.

The position at which the magnetic bodies 64A are provided on the guard ring 6A may be changed as appropriate. For example, the magnetic bodies 64A may be provided in a region of the inner wall of the hollow 62A that is located on the radially inner side.

### 5. Application Examples

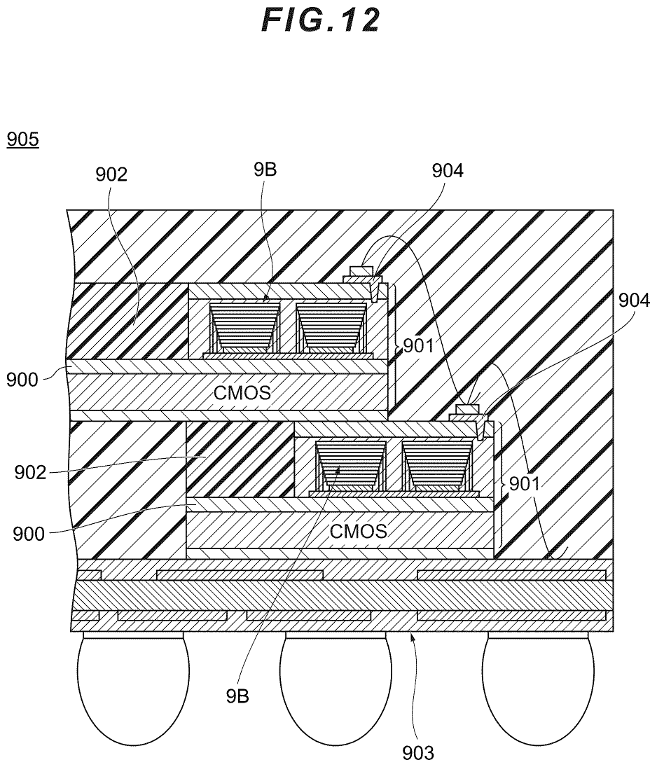

With the semiconductor manufacturing equipment and the method for manufacturing semiconductor devices according to some embodiments, the chips 9B in which the cell array is formed, for example, are manufactured. As shown in FIG. 12, the chip 9B may be bonded to a wafer, on which a peripheral circuit such as a CMOS (complementary metal oxide semiconductor) has been formed, with a bonding pad 900 interposed therebetween to constitute part of a three-dimensional memory 901. In other words, the chips 9B may each be affixed to a peripheral circuit (on a chip basis) provided on a wafer different from the silicon wafer 90 so as to constitute part of the three-dimensional memory 901. Herein, the peripheral circuit may have a length in a first direction longer than a length of the chip 9B in the first direction. Accordingly, there may be a vacant space in which the chip 9B is not stacked on the peripheral circuit in the three-dimensional memory 901, but the vacant space may be filled with epoxy molding resin 902 or the like. The three-dimensional memory 901 may be stacked on the substrate 903 together with another semiconductor device not shown and the like and may each be connected to the substrate 903 with a bonding pad 904 interposed therebetween. The chip 9B may thus be incorporated into a package substrate 905. A method for manufacturing the three-dimensional memory 901 including the chip 9B as illustrated above and the package substrate 905 is also encompassed in the scope of the present disclosure.

While certain embodiments have been described, these embodiments have been presented by way of example only, and are not intended to limit the scope of the inventions. Indeed, the novel devices and methods described herein may be embodied in a variety of other forms; furthermore, various omissions, substitutions and changes in the form of the embodiments described herein may be made without departing from the spirit of the inventions. The accompanying claims and their equivalents are intended to cover such forms or modification as would fall within the scope and spirit of the inventions.

What is claimed is:

1. Semiconductor manufacturing equipment comprising:
a processing chamber for processing a substrate having a surface on which a photoresist film is formed;
a stage provided in the processing chamber and configured to support the substrate such that the photoresist film faces upward;
an edge ring that is annular and configured to enclose the substrate in a state supported on the stage;
a guard ring that is annular and configured to cover from above a circumferential edge of the substrate in the state supported on the stage; and
a conveyor configured to convey at least the guard ring in the processing chamber, wherein a recess is formed in one of an upper surface portion of the edge ring and a lower surface portion of the guard ring,
a projection that is engageable with the recess is formed on the other one of the upper surface portion of the edge ring and the lower surface portion of the guard ring,
the guard ring is configured such that an inner circumferential end of the guard ring is located between an outer circumferential end of the substrate supported on the stage and an outer circumferential end of the photoresist film in a state in which the recess and the projection are engaged, and
the conveyor is configured to convey the guard ring onto the edge ring and engage the recess and the projection.

2. The semiconductor manufacturing equipment according to claim 1, further comprising:
a first sensor provided for the conveyor and configured to detect the recess or the projection formed in or on the upper surface portion of the edge ring; and
a controller configured to control a position of the conveyor based on an output from the first sensor.

3. The semiconductor manufacturing equipment according to claim 2, further comprising at least three lift pins configured to be projectable upward from the stage and arranged at intervals on a circumference of a virtual circle, wherein
the virtual circle has a diameter larger than an inner diameter of the edge ring and smaller than an outer diameter of the edge ring,
at least three notches or through-holes are formed in the edge ring, the at least three notches or through-holes being configured such that the lift pins are respectively insertable when the edge ring is arranged to be concentric with the virtual circle, and
the at least three lift pins are configured to project upward from the stage to support the guard ring.

4. The semiconductor manufacturing equipment according to claim 3, wherein each of the lift pins is configured to be changeable at least in one of a position in an in-plane direction parallel to an upper surface of the stage and an inclination angle relative to the upper surface of the stage, the semiconductor manufacturing equipment further comprising:
a second sensor configured to detect the outer circumferential end of the photoresist film of the substrate in the state supported on the stage; and
a controller configured to control at least one of the position in the in-plane direction of each of the lift pins and the inclination angle relative to the upper surface of the stage based on an output from the second sensor.

5. The semiconductor manufacturing equipment according to claim 3, wherein the guard ring has hollows formed in the lower surface portion, the hollows being engageable with leading ends of the lift pins, respectively, when the guard ring is arranged to be concentric with the virtual circle, the semiconductor manufacturing equipment further comprising:
magnetic bodies provided in the hollows, respectively;
electromagnets provided at the leading ends of the lift pins, respectively;
a second sensor configured to detect a position of the outer circumferential end of the photoresist film of the substrate in the state supported on the stage; and
a controller configured to adjust a magnetic force of each of the electromagnets based on an output from the second sensor.

6. The semiconductor manufacturing equipment according to claim 1, wherein the guard ring is configured such that a distance between the inner circumferential end of the guard ring and the outer circumferential end of the photoresist film is less than 200 μm in the state in which the recess and the projection are engaged.

7. The semiconductor manufacturing equipment according to claim 2, wherein the guard ring is configured such that a distance between the inner circumferential end of the guard ring and the outer circumferential end of the photoresist film is less than 200 μm in the state in which the recess and the projection are engaged.

8. The semiconductor manufacturing equipment according to claim 3, wherein the guard ring is configured such that a distance between the inner circumferential end of the guard ring and the outer circumferential end of the photoresist film is less than 200 μm in the state in which the recess and the projection are engaged.

9. The semiconductor manufacturing equipment according to claim 4, wherein the guard ring is configured such that a distance between the inner circumferential end of the guard ring and the outer circumferential end of the photoresist film is less than 200 μm in the state in which the recess and the projection are engaged.

10. The semiconductor manufacturing equipment according to claim 5, wherein the guard ring is configured such that a distance between the inner circumferential end of the guard ring and the outer circumferential end of the photoresist film is less than 200 μm in the state in which the recess and the projection are engaged.

11. A method for manufacturing semiconductor devices, the method comprising:
preparing semiconductor manufacturing equipment including
a processing chamber for processing a first substrate having a surface on which a photoresist film is formed,
a stage provided in the processing chamber and configured to support the first substrate such that the photoresist film faces upward,
an edge ring that is annular and configured to enclose the first substrate in a state supported on the stage,
a guard ring that is annular and configured to cover from above a circumferential edge of the first substrate in the state supported on the stage, and
a conveyor configured to convey at least the guard ring in the processing chamber,
a recess being formed in one of an upper surface portion of the edge ring and a lower surface portion of the guard ring,
a projection that is engageable with the recess being formed on the other one of the upper surface portion of the edge ring and the lower surface portion of the guard ring,
the guard ring being configured such that an inner circumferential end of the guard ring is located between an outer circumferential end of the first substrate supported on the stage and an outer circumferential end of the photoresist film in a state in which the recess and the projection are engaged,
the conveyor being configured to convey the guard ring onto the edge ring and engage the recess and the projection;
placing, on an inner side of the edge ring, the first substrate on which the photoresist film is formed;
placing the guard ring on the edge ring by the conveyor such that the recess and the projection are engaged; and
cutting the first substrate between the inner circumferential end of the guard ring and the outer circumferential end of the photoresist film in a state in which the guard ring is placed on the edge ring.

12. The method for manufacturing semiconductor devices according to claim 11, wherein placing the guard ring on the edge ring includes placing the guard ring on the edge ring such that a distance between the inner circumferential end of the guard ring and the outer circumferential end of the photoresist film is less than 200 μm in the state in which the recess and the projection are engaged.

13. The method for manufacturing semiconductor devices according to claim 11, wherein cutting the first substrate is cutting through reactive ion etching.

14. The method for manufacturing semiconductor devices according to claim 13, wherein the reactive ion etching is plasma etching.

15. The method for manufacturing semiconductor devices according to claim 11, wherein
the photoresist film forms a dicing pattern, the method further comprising
cutting part of the first substrate along the dicing pattern in parallel to cutting the first substrate.

16. The method for manufacturing semiconductor devices according to claim 11, further comprising:
polishing the first substrate cut between the inner circumferential end of the guard ring and the outer circumferential end of the photoresist film and dicing the first substrate into a plurality of chips;
transferring the plurality of chips to a pickup tape;
expanding the pickup tape to pick up the plurality of chips; and
bonding at least one chip among the plurality of chips having been diced to a peripheral circuit provided on a second substrate different from the first substrate, wherein
the peripheral circuit has a length in a first direction longer than a length in the first direction of the at least one chip.

17. The method for manufacturing semiconductor devices according to claim 11, wherein
the semiconductor manufacturing equipment further includes a first sensor configured to detect the recess or the projection formed in or on the upper surface portion of the edge ring, and
placing the guard ring on the edge ring includes controlling a position of the conveyor based on an output from the first sensor.

18. The method for manufacturing semiconductor devices according to claim 11, wherein
the semiconductor manufacturing equipment further includes at least three lift pins configured to be projectable upward from the stage and arranged at intervals on a circumference of a virtual circle,
the virtual circle has a diameter larger than an inner diameter of the edge ring and smaller than an outer diameter of the edge ring,
at least three notches or through-holes are formed in the edge ring, the at least three notches or through-holes being configured such that the lift pins are respectively insertable when the edge ring is arranged to be concentric with the virtual circle,
the method further comprising positioning the edge ring on the stage to be concentric with the virtual circle, wherein
placing the guard ring on the edge ring further includes causing the at least three lift pins to project upward from the stage and supporting the guard ring with the at least three lift pins.

19. The method for manufacturing semiconductor devices according to claim 18, wherein
the semiconductor manufacturing equipment further includes a second sensor configured to detect the outer circumferential end of the photoresist film of the first substrate in the state supported on the stage,
each of the at least three lift pins is configured to be changeable at least in one of a position in an in-plane direction parallel to an upper surface of the stage and an inclination angle relative to the upper surface of the stage, and
placing the guard ring on the edge ring further includes controlling at least one of the position in the in-plane direction of each of the at least three lift pins and the inclination angle relative to the upper surface of the stage based on an output from the second sensor to adjust at least one of a position in a horizontal direction of the guard ring supported by the at least three lift pins and an inclination relative to a horizontal plane.

20. The method for manufacturing semiconductor devices according to claim 18, wherein
the guard ring has hollows formed in the lower surface portion, the hollows being engageable with leading ends of the lift pins, respectively, when the guard ring is arranged to be concentric with the virtual circle,
the semiconductor manufacturing equipment further includes
magnetic bodies provided in the hollows, respectively,
electromagnets provided at the leading ends of the lift pins, respectively, and
a second sensor configured to detect a position of the outer circumferential end of the photoresist film of the first substrate in the state supported on the stage, and
placing the guard ring on the edge ring further includes adjusting a magnetic force of each of the electromagnets based on an output from the second sensor in a state in which the hollows and the lift pins are engaged, respectively, to adjust a position of the inner circumferential end of the guard ring.
